(19) United States
(12) Patent Application Publication
(10) Pub. No.: US 2025/0261369 A1
(43) Pub. Date: Aug. 14, 2025

(54) SEMICONDUCTOR DEVICE MANUFACTURING METHOD

(71) Applicant: Kioxia Corporation, Tokyo (JP)

(72) Inventors: Ryota FUJITSUKA, Yokkaichi (JP); Yuta MIDO, Yokkaichi (JP); Takanori YAMANAKA, Yokkaichi (JP); Keiichi SAWA, Yokkaichi (JP)

(73) Assignee: Kioxia Corporation, Tokyo (JP)

(21) Appl. No.: 18/822,607

(22) Filed: Sep. 3, 2024

(30) Foreign Application Priority Data
Feb. 14, 2024 (JP) 2024-020553

(51) Int. Cl. H10B 43/27

(52) U.S. Cl. CPC H10B 43/27

(57) ABSTRACT

A semiconductor device manufacturing method according to the present embodiment includes forming a structure including a first surface and a second surface, the first surface containing SiO₂ and being exposed, the second surface containing SiN, being exposed, and provided at a position different from a position of the first surface. The present manufacturing method further includes selectively forming an insulation part containing SiO₂ on the first surface. Selectively forming the insulation part on the first surface includes performing treatment using an Si precursor and an oxidant, the Si precursor containing an amino group and an alkoxy group, the oxidant containing O₂ or H₂O.

### CROSS REFERENCE TO RELATED APPLICATIONS

This application is based upon and claims the benefit of priority from the prior Japanese Patent Application No. 2024-020553, filed on Feb. 14, 2024, the entire contents of which are incorporated herein by reference.

### FIELD

The embodiments of the present invention relate to a semiconductor device manufacturing method.

### BACKGROUND

In a structure including a plurality of exposed underlaying surfaces containing materials different from one another, a material is selectively grown on one of the underlaying surfaces in some cases. However, it is sometimes difficult to ensure selectiveness, which results in false growth.

### BRIEF DESCRIPTION OF THE DRAWINGS

FIG. 1 is a block diagram illustrating a configuration example of a memory;

FIG. 2 is a circuit diagram illustrating a circuit configuration of a memory cell array;

FIG. 3 is a cross-sectional schematic diagram for description of a first structure example of a NAND string according to an embodiment;

FIG. 4 is a cross-sectional schematic diagram along line segment A-B in FIG. 3;

FIG. 5 is an enlarged view illustrating part of FIG. 3;

FIG. 6 is a cross-sectional schematic diagram for description of a first formation method example for the first structure example of the NAND string;

FIG. 7 is a cross-sectional schematic diagram for description of the first formation method example for the first structure example of the NAND string;

FIG. 8 is a cross-sectional schematic diagram for description of the first formation method example for the first structure example of the NAND string;

FIG. 9 is a cross-sectional schematic diagram for description of the first formation method example for the first structure example of the NAND string;

FIG. 10 is a cross-sectional schematic diagram for description of the first formation method example for the first structure example of the NAND string;

FIG. 11 is a cross-sectional schematic diagram for description of the first formation method example for the first structure example of the NAND string;

FIG. 12 is a cross-sectional schematic diagram for description of the first formation method example for the first structure example of the NAND string;

FIG. 13 is a cross-sectional schematic diagram for description of the first formation method example for the first structure example of the NAND string;

FIG. 14 is a graph for description of an example of cycle number dependency of stacked layer thickness in the first formation method example;

FIG. 15 is a cross-sectional schematic diagram for description of a second formation method example for the first structure example of the NAND string;

FIG. 16 is a cross-sectional schematic diagram for description of the second formation method example for the first structure example of the NAND string;

FIG. 17 is a cross-sectional schematic diagram for description of a second structure example of the NAND string according to the embodiment;

FIG. 18 is a cross-sectional schematic diagram along line segment A-B in FIG. 17; and

FIG. 19 is an enlarged view illustrating part of FIG. 17.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device manufacturing method according to the present embodiment includes forming a structure including a first surface and a second surface, the first surface containing SiO₂ and being exposed, the second surface containing SiN, being exposed, and provided at a position different from the position of the first surface. The present manufacturing method further includes selectively forming an insulation part containing SiO₂ on the first surface. Selectively forming the insulation part on the first surface includes performing treatment using a Si precursor and an oxidant, the Si precursor containing an amino group and an alkoxy group, the oxidant containing O₂ or H₂O.

In the present specification, “connection” includes not only physical connection but also electrical connection unless otherwise stated.

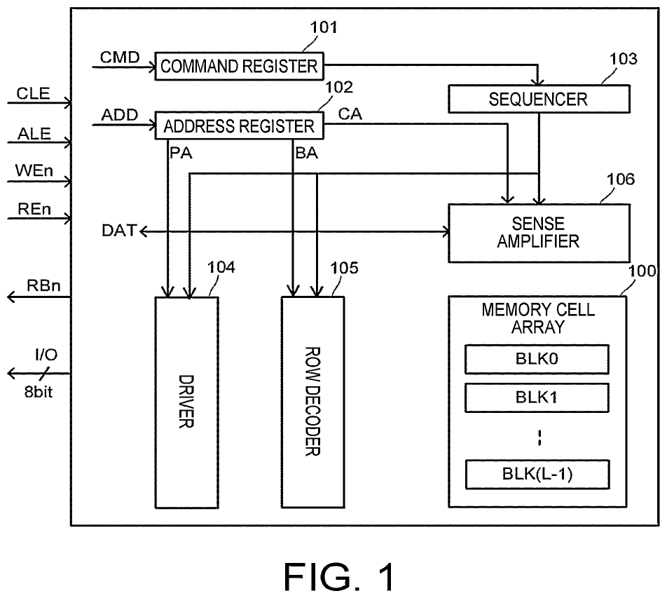

A configuration example of a semiconductor storage device (semiconductor device) will be described below. FIG. 1 is a block diagram illustrating a configuration example of a memory. The memory includes a memory cell array 100, a command register 101, an address register 102, a sequencer 103, a driver 104, a row decoder 105, and a sense amplifier 106.

The memory cell array 100 includes a plurality of blocks BLK (BLK0 to BLK (L-1) (L is a natural number equal to or larger than two)). Each block BLK is a set of a plurality of memory cells for storing data.

The command register 101 holds a command signal CMD received from a memory controller. The command signal CMD includes, for example, command data that causes the sequencer 103 to execute read operation, write operation, and delete operation.

The address register 102 holds an address signal ADD received from the memory controller. The address signal ADD includes, for example, a block address BA, a page address PA, and a column address CA. For example, the block address BA, the page address PA, and the column address CA are used for selection of a block BLK, a word line WL, and a bit line BL, respectively.

The sequencer 103 controls operation of the memory. For example, the sequencer 103 executes operation such as read operation, write operation, and delete operation by controlling the driver 104, the row decoder 105, the sense amplifier 106, and the like based on the command signal CMD held by the command register 101.

The driver 104 generates voltage used in read operation, write operation, delete operation, and the like. The driver 104 includes, for example, a DA converter. For example, the driver 104 applies generated voltage to a signal line corresponding to a selected word line WL based on the page address PA held by the address register 102.

The row decoder 105 selects one corresponding block BLK in the memory cell array 100 based on the block address BA held by the address register 102. Then, the row decoder 105 forwards, for example, to a selected word line WL in the selected block BLK, the voltage applied to the signal line corresponding to the selected word line WL.

In write operation, the sense amplifier 106 applies desired voltage to bit lines BL in accordance with write data DAT received from the memory controller. In read operation, the sense amplifier 106 determines data stored in memory cells based on voltage of bit lines BL and forwards a result of the determination as read data DAT to the memory controller.

Communication between the memory and the memory controller supports, for example, a NAND interface standard. For example, communication between the memory and the memory controller uses a command latch enable signal CLE, an address latch enable signal ALE, a write enable signal WEn, a read enable signal REn, a ready/busy signal RBn, and an input/output signal I/O.

The command latch enable signal CLE indicates that the input/output signal I/O received by the memory is the command signal CMD. The address latch enable signal ALE indicates that the received signal I/O is the address signal ADD. The write enable signal WEn is a signal that commands the memory to input the input/output signal I/O. The read enable signal REn is a signal that commands the memory to output the input/output signal I/O.

The ready/busy signal RBn is a signal that notifies, to the memory controller, whether the memory is in a ready state to receive commands from the memory controller or in a busy state not receiving commands.

The input/output signal I/O is, for example, an 8-bit wide signal and can include signals such as the command signal CMD, the address signal ADD, and a write data signal DAT.

The memory and the memory controller described above may be combined to configure one semiconductor storage device. Examples of such a semiconductor storage device include a memory card such as an SD card, and a solid-state drive (SSD).

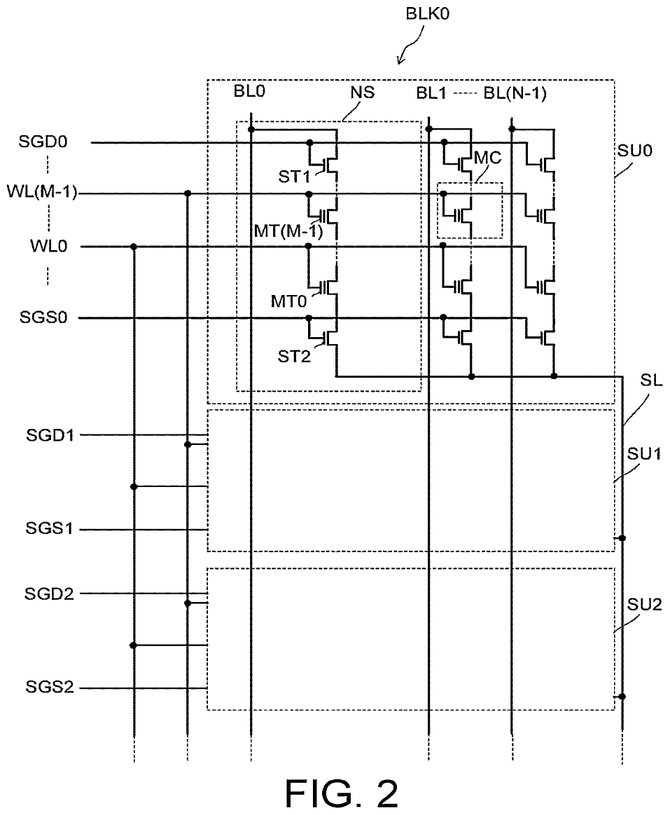

A circuit configuration example of the memory cell array 100 will be described next. FIG. 2 is a circuit diagram illustrating a circuit configuration of the memory cell array 100. The configuration of the block BLK0, which is exemplarily illustrated in FIG. 2, is the same as those of the other blocks BLK.

Each block BLK includes a plurality of string units SU. Each string unit SU includes a plurality of NAND strings NS. Although FIG. 2 illustrates three string units SU (SU0 to SU2), the number of string units SU is not particularly limited.

Each NAND string NS is connected to one of a plurality of bit lines BL (BL0 to BL(N-1) (N is a natural number equal to or larger than two)). Each NAND string NS includes, for example, memory transistors MT, a selection transistor ST1, and a selection transistor ST2. Each memory transistor MT constitutes one memory cell MC. Each NAND string NS includes a plurality of memory cells connected in series. Such a memory including memory cells is also referred to as a chain-type memory.

Each memory transistor MT includes a control gate and a charge trap layer and can non-transitorily hold data. The memory transistor MT may be of a MONOS type in which an insulating film is used as the charge trap layer, or may be of an FG type in which an electric conductor layer is used as the charge trap layer. The following description of the embodiment will be made on the MONOS type as an example.

The control gate of each memory transistor MT is connected to a corresponding word line WL. One of the source and drain of one of a plurality of memory transistors MT is connected to the other of the source and drain of another one of the plurality of memory transistors MT. Although FIG. 2 illustrates a plurality of memory transistors MT (MT0 to MT(M-1) (M is a natural number equal to or larger than two)), the number of memory transistors MT is not particularly limited.

The selection transistor ST1 is used to select the corresponding string unit SU in various kinds of operation. The number of selection transistors ST1 is not particularly limited.

The selection transistor ST2 is used to select the corresponding string unit SU in various kinds of operation. The number of selection transistors ST2 is not particularly limited.

In each NAND string NS, the drain of the selection transistor ST1 is connected to the corresponding bit line BL. The source of the selection transistor ST1 is connected to one end of the memory transistors MT connected in series. The other end of the memory transistors MT connected in series is connected to the drain of the selection transistor ST2.

In the same block BLK, the source of each selection transistor ST2 is connected to a source line SL. The gate of each selection transistor ST1 of each string unit SU is connected to a corresponding select gate line SGD. The gate of each memory transistor MT is connected to a corresponding word line WL. The gate of each selection transistor ST2 is connected to a corresponding select gate line SGS.

A plurality of NAND strings NS to which the same column address CA is allocated are connected to the same bit line BL among a plurality of blocks BLK. The source line SL is connected among a plurality of blocks BLK.

A structure example of each NAND string NS will be described next.

Each NAND string NS in the embodiment has, for example, either of a first structure example or a second structure example described below. Each structure example will be described below.

### First Structure Example of NAND String NS

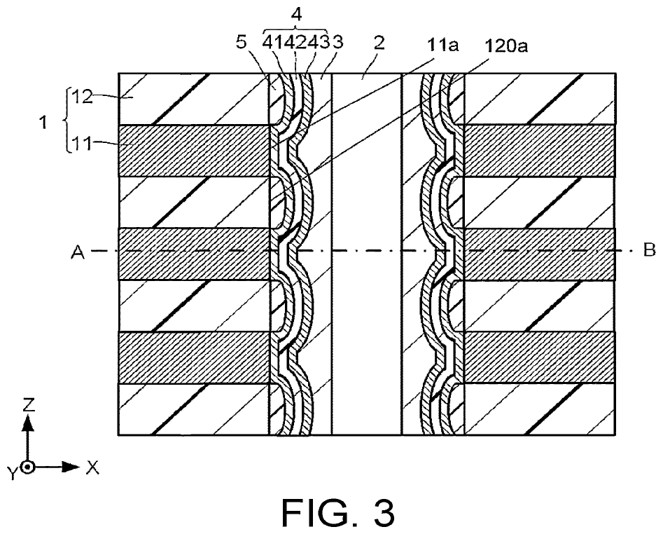

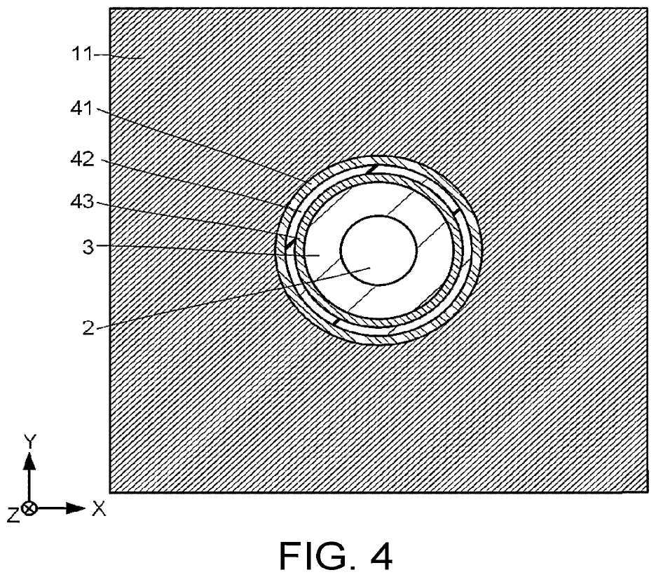

FIG. 3 is a cross-sectional schematic diagram for description of the first structure example of each NAND string NS in the embodiment. FIG. 3 illustrates an X axis, a Y axis orthogonal to the X axis, and a Z axis orthogonal to the X and Y axes and illustrates part of an X-Z section including the X and Z axes. FIG. 4 is a cross-sectional schematic diagram along line segment A-B in FIG. 3 and illustrates part of an X-Y section including the X and Y axes.

As illustrated in FIGS. 3 and 4, the NAND string NS includes a stacked body 1, an insulator 2, a semiconductor layer 3, a memory layer 4, and an insulation part 5.

The stacked body 1 includes a conductive layer 11 and an insulating layer 12. A plurality of the conductive layers 11 and a plurality of the insulating layers 12 are alternately stacked in the Z-axis direction. Each conductive layer 11 constitutes a word line WL and a gate electrode of a memory transistor MT and extends in the X-axis direction or the Y-axis direction. Examples of the conductive layers 11 include a conductive layer such as a tungsten layer. Examples of the insulating layers 12 include a silicon oxide layer. In the Z-axis direction, a surface 11a of each conductive layer 11, which faces the memory layer 4 may be flush with a surface 120a of each insulating layer 12, which faces the insulation part 5. Each conductive layer 11 may have a stacked structure of a plurality of layers. The stacked structure may include, for example, a tungsten layer, a titanium nitride layer, and an aluminum oxide layer.

The insulator 2 is provided, for example, in the stacking direction (Z-axis direction) of the conductive layers 11 and the insulating layers 12. The insulator 2 functions as a core insulator. The insulator 2 has, for example, a cylindrical shape. Examples of the insulator 2 include a silicon oxide layer. The NAND string NS does not necessarily need to include the insulator 2. As illustrated in FIG. 4, the semiconductor layer 3 surrounds the insulator 2 at the section A-B. The semiconductor layer 3 penetrates through the stacked body 1 in the Z-axis direction. The semiconductor layer 3 contains, for example, polysilicon. The semiconductor layer 3 forms a channel region of each memory transistor MT. The semiconductor layer 3 is electrically connected to the bit lines BL and the source line SL. The outer periphery of the semiconductor layer 3 is covered with the memory layer 4.

The memory layer 4 is provided on a side opposite the insulator 2 with respect to the semiconductor layer 3. The memory layer 4 is provided between each conductive layer 11 and the semiconductor layer 3 and between each insulating layer 12 and the semiconductor layer 3 in the X-axis direction or the Y-axis direction. The memory layer 4 surrounds the semiconductor layer 3 at the section A-B as illustrated in FIG. 4.

The memory layer 4 includes a block insulating film 41, a charge trap film 42, and a tunnel insulating film 43. The block insulating film 41 is provided between the insulation part 5 and the semiconductor layer 3 in the X-axis direction or the Y-axis direction and contains, for example, oxygen and silicon. The charge trap film 42 is provided between the tunnel insulating film 43 and the block insulating film 41 in the X-axis direction or the Y-axis direction and contains, for example, nitrogen and silicon. The tunnel insulating film 43 is provided between the charge trap film 42 and the semiconductor layer 3 and includes, for example, oxygen, nitrogen, and silicon.

The insulation part 5 extends from each insulating layer 12 toward the semiconductor layer 3 in the X-axis direction or the Y-axis direction. The insulation part 5 is provided on each surface 120a. The insulation part 5 is provided between each insulating layer 12 and the memory layer 4. The insulation part 5 surrounds the semiconductor layer 3. The insulation part 5 contains, for example, silicon and oxygen. In a case where the insulation part 5 contains the same material as that of the insulating layers 12, the interface between the insulation part 5 and each insulating layer 12 cannot be clearly visually recognized even with a device such as a transmission electron microscope (TEM) in some cases. In such a case, a part overlapping a line segment connecting surfaces of the conductive layers 11 above and below each insulating layer 12, the surfaces facing the block insulating film 41 may be regarded as the interface between the insulation part 5 and the insulating layer 12.

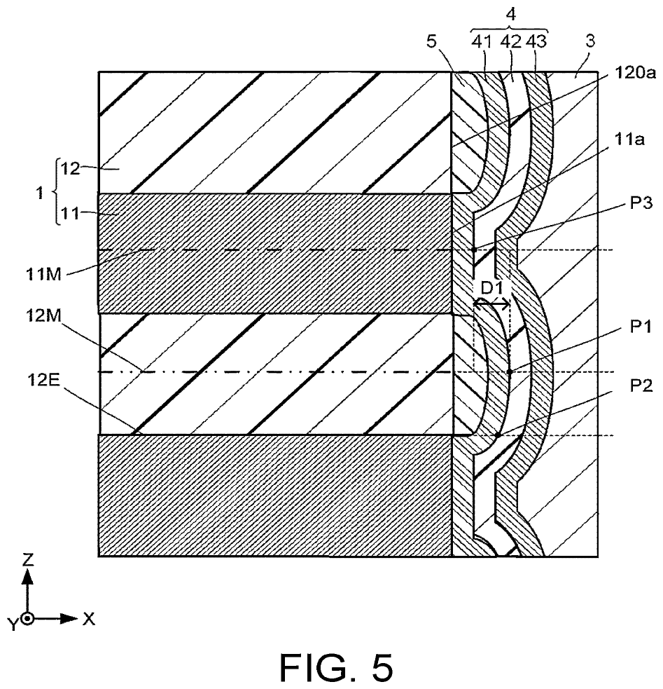

FIG. 5 is an enlarged view illustrating part of FIG. 3. At a section of the NAND string NS in the Z-axis direction, including the conductive layers 11, the insulating layers 12, the semiconductor layer 3, the memory layer 4, and the insulation part 5, each of the interface between the block insulating film 41 and the charge trap film 42, the interface between the charge trap film 42 and the tunnel insulating film 43, and the interface between the tunnel insulating film 43 and the semiconductor layer 3 includes a first part, a second part, and a third part. In the X-axis direction or the Y-axis direction, the first part overlaps a central part 12M of an insulating layer 12 in the Z-axis direction. In the X-axis direction or the Y-axis direction, the second part overlaps an end part 12E of an insulating layer 12 in the Z-axis direction. The third part overlaps a central part 11M of a conductive layer 11 in the Z-axis direction. The central part 11M is, for example, a region positioned at a depth separated from the upper surface or lower surface of the conductive layer 11 by half of the thickness (length in the Z-axis direction) of the conductive layer 11. The central part 12M is, for example, a region positioned at a depth separated from the upper surface or lower surface of the insulating layer 12 by half of the thickness (length in the Z-axis direction) of the insulating layer 12. The end part 12E is a region contacting an end part of the conductive layer 11 in the Z-axis direction. The second part is provided on each of the upper and lower sides of the first part. FIG. 5 illustrates an example in which the interface between the block insulating film 41 and the charge trap film 42 includes a part P1 overlapping the central part 12M of the insulating layer 12 in the Z-axis direction, a part P2 overlapping the end part 12E, and a part P3 overlapping the central part 11M.

At each interface, the second part is closer to the insulating layer 12 than the first part in the X-axis direction or the Y-axis direction. Each interface has a round or arch shape protruding toward the memory layer 4. Each interface curves in a convex shape toward the semiconductor layer 3 from the second parts on the upper and lower sides to the first part. For example, the interface between the block insulating film 41 and the charge trap film 42 curves in a convex shape toward the semiconductor layer 3 from the parts P2 on the upper and lower sides to the part P1 as illustrated in FIG. 5.

At each interface, an interval D1 between the first part and the third part in the X-axis direction or the Y-axis direction is preferably equal to or larger than 0.5 nm and equal to or smaller than 5 nm. In a case where the interval D1 is smaller than 0.5 nm, it is difficult to prevent electric interference between adjacent memory cells MC. In a case where the interval D1 is larger than 5 nm, electric field concentrates at the central part 11M, for example, when voltage is applied to a gate electrode WL, and as a result, writing efficiency decreases in some cases.

The thickness (length in the X-axis direction or the Y-axis direction) of the insulation part 5 is preferably equal to or larger than 0.5 nm and equal to or smaller than 5 nm. This means that the thickness of the entire region from a part where the thickness of the insulation part 5 is minimum to a part where the thickness of the insulation part 5 is maximum may be equal to or larger than 0.5 nm and equal to or smaller than 5 nm.

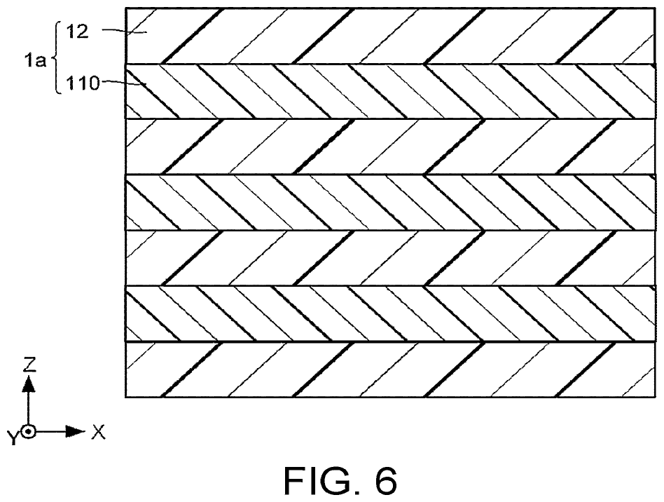

A first formation method example for the first structure example of each NAND string NS in a semiconductor storage device manufacturing method will be described below with reference to FIGS. 6 to 13. FIGS. 6 to 13 are cross-sectional schematic diagrams for description of the first formation method example for the first structure example of each NAND string NS, and illustrate part of an X-Z section.

First, as illustrated in FIG. 6, insulating layers 110 and insulating layers 12 are alternately stacked in the Z-axis direction to form a stacked body 1a. Each insulating layer 110 is a sacrifice layer. A sacrifice layer is a layer for forming a space later. Examples of the insulating layers 110 include a silicon nitride layer.

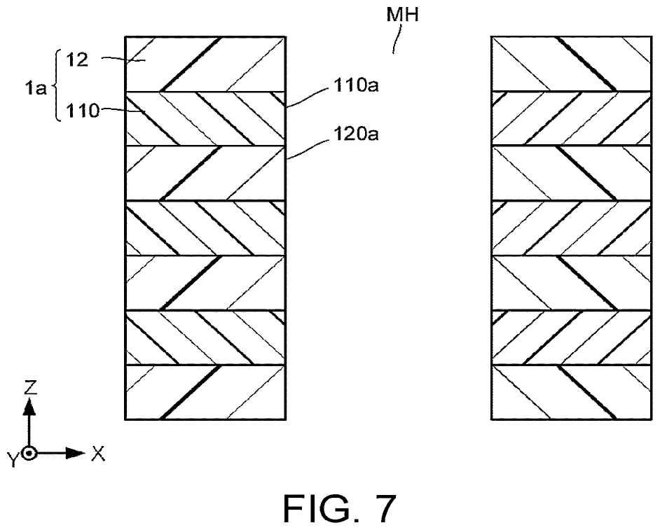

Subsequently, as illustrated in FIG. 7, the stacked body 1a is fabricated to form an opening (memory hole MH), surfaces 110a, and surfaces 120a, the opening penetrating through the stacked body 1a in the Z-axis direction. The surfaces 110a are provided at the insulating layers 110 and face the memory hole MH. The surfaces 120a are provided at the insulating layers 12 and face the memory hole MH. The stacked body 1a can be fabricated by using, for example, reactive ion etching (RIE).

In the example illustrated in FIG. 7, the surfaces 110a and 120a are exposed at the inner surface of the memory hole MH. The surfaces 110a are provided at positions different from the positions of the surfaces 120a. The positions of the surfaces 110a and 120a are, for example, positions on the inner surface of the memory hole MH. The surfaces 120a contain SiO₂, and the surfaces 110a contain SiN.

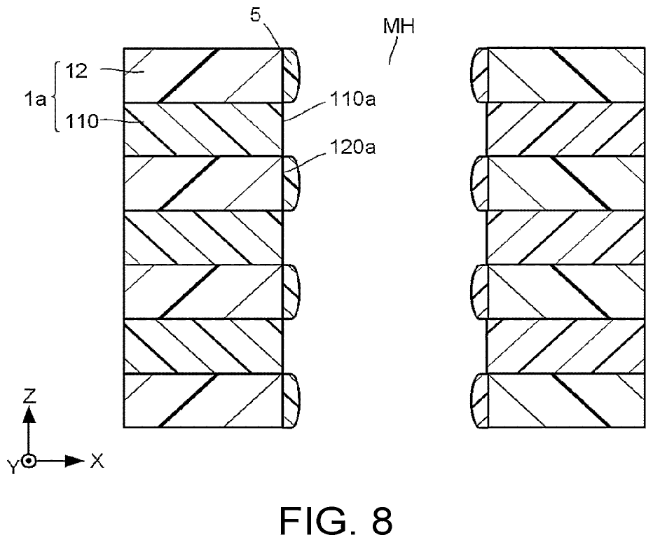

Subsequently, as illustrated in FIG. 8, the insulation part 5 is selectively formed on the surface 120a of each insulating layer 12. The insulation part 5 can be formed by using, for example, a selective growth method. In a case where the insulation part 5 containing, for example, silicon oxide is formed by the selective growth method, the insulation part 5 is formed by using gas and an oxidant, the gas containing a silicon (Si) precursor that can be selectively adsorbed onto an OH group on the surface 120a of each insulating layer 12 as a silicon oxide film. The oxidant is preferably, for example, O₂ or H₂O. The method of forming the insulation part 5 is not limited to the above-described method. The insulation part 5 may be formed by using, for example, chemical vapor deposition (CVD) or atom layer deposition (ALD).

More specifically, in the ALD, an ALD cycle is executed a plurality of times. In the ALD, one ALD cycle includes supplying gas containing the Si precursor to a chamber of a semiconductor manufacturing device, performing vacuuming/purging, supplying gas containing the oxidant, and performing vacuuming/purging.

The Si precursor contains, for example, an amino group and an alkoxy group. The Si precursor is, for example, aminoalkoxysilane. More specifically, the Si precursor is, for example, diisopropylaminotriethoxylsilane (DIPATEOS). However, the Si precursor is not limited thereto as described later.

With the supply of the Si precursor, the amino group of the Si precursor is cleaved and the Si precursor is selectively adsorbed onto the OH group of SiO₂. This is because the activation energy of chemical adsorption reaction of the Si precursor is greater for an NH group than for an OH group. Thereafter, with the supply of the oxidant, the alkoxy group of the Si precursor is oxidized and the Si precursor is replaced with SiO₂. The alkoxy group includes oxygen (O) in its molecule structure and is oxidized through oxidation treatment with relatively small oxidation power. With the ALD using an oxidant with small oxidation power, it is possible to reduce oxidation of SiN on the surfaces 110a, thereby preventing the NH group on the surfaces 110a from being replaced with an OH group. This can make it easier to selectively grow SiO₂ on the surfaces 120a. In other words, selectiveness can be increased.

The oxidant is not limited to O₂ nor H₂O and may include a material with small oxidation power so that an OH group is unlikely to be formed on the surfaces 110a (outermost surface of SiN).

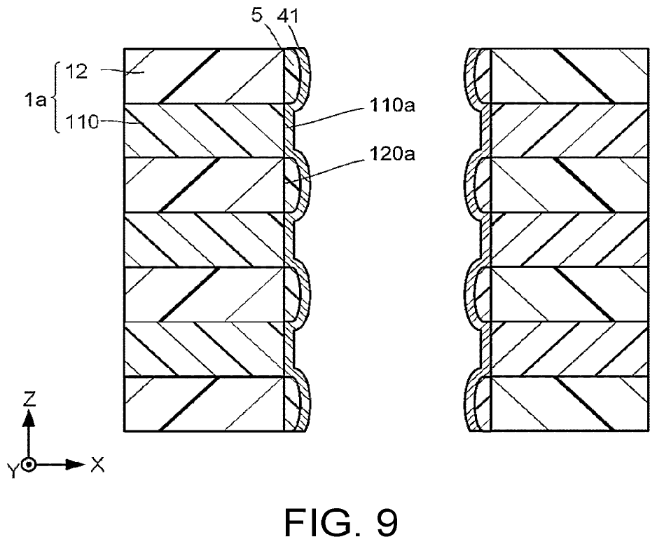

Subsequently, as illustrated in FIG. 9, the block insulating film 41 is formed on the surfaces 110a and the surface of the insulation part 5. The block insulating film 41 can be formed by using, for example, the CVD or the ALD.

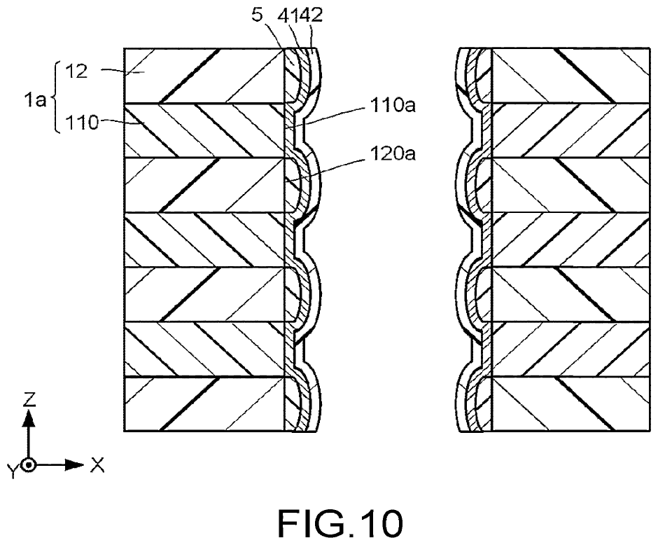

Subsequently, as illustrated in FIG. 10, the charge trap film 42 is formed on the surface of the block insulating film 41. The charge trap film 42 can be formed by using, for example, the CVD or the ALD.

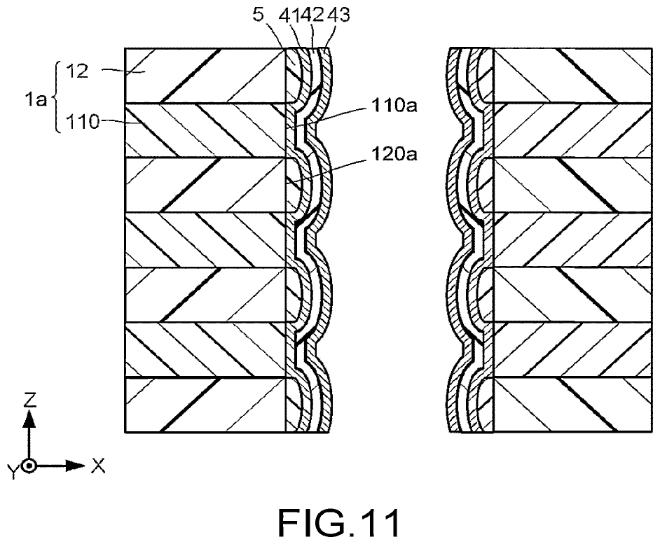

Subsequently, as illustrated in FIG. 11, the tunnel insulating film 43 is formed on the surface of the charge trap film 42. The tunnel insulating film 43 can be formed by using, for example, the CVD or the ALD.

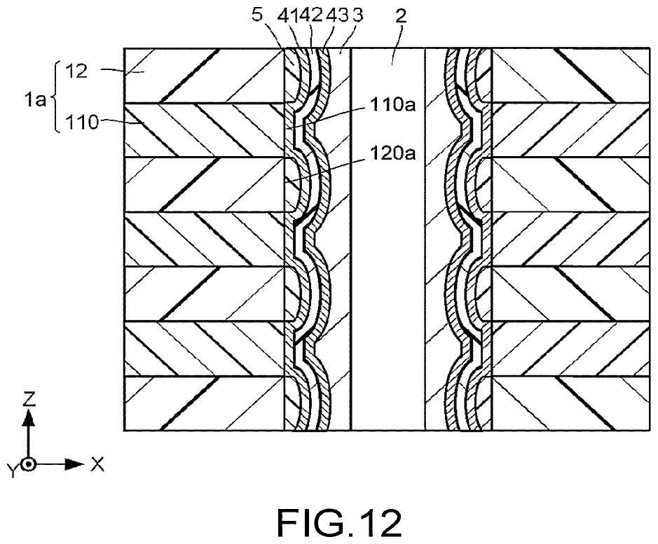

Subsequently, as illustrated in FIG. 12, the semiconductor layer 3 is formed on the surface of the tunnel insulating film 43, and the insulator 2 is formed on the surface of the semiconductor layer 3. The semiconductor layer 3 and the insulator 2 can be formed by using, for example, the CVD or the ALD.

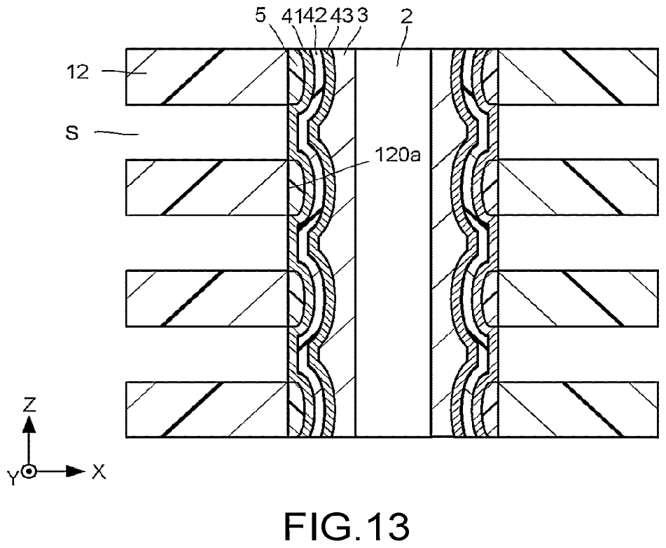

Subsequently, as illustrated in FIG. 13, the insulating layers 110 is removed to form spaces S, and thereafter, the conductive layers 11 are formed in the spaces S. The insulating layers 110 can be removed by using, for example, wet etching or dry etching. The conductive layers 11 can be formed by using, for example, the CVD or the ALD. Through the above-described process, the first structure example of each NAND string NS can be formed.

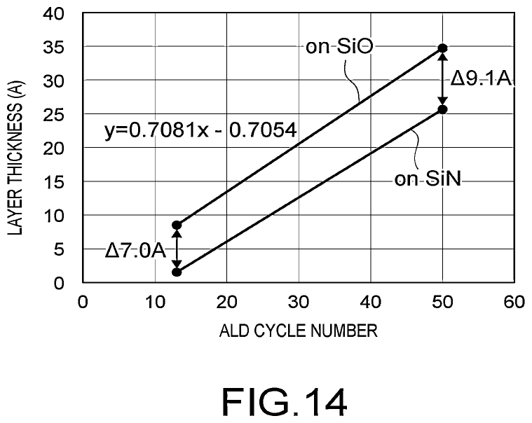

FIG. 14 is a graph for description of an example of cycle number dependency of stacked layer thickness in the first formation method example. The vertical axis represents the layer thickness (Å) of SiO₂ deposited by the ALD. The horizontal axis represents the number of ALD cycles. In the example illustrated in FIG. 14, aminoalkoxysilane is used as the Si precursor, O₂ is used as the oxidant, and the treatment temperature of the ALD is 400° C. approximately.

In the example illustrated in FIG. 14, SiO₂ on the surfaces 120a (SiO₂) is thicker than SiO₂ on the surfaces 110a (SiN). In other words, incubation is more significant on the surface 110a (SiN) than on the surfaces 120a (SiO₂). Moreover, the layer thickness of SiO₂ on the surfaces 110a and 120a increases as the number of ALD cycles increases.

Deposition of SiO₂ on the surfaces 110a (SiN) starts in 10 ALD cycles approximately. The layer thickness difference of SiO₂ between on the surfaces 120a and on the surfaces 110a in 10 ALD cycles approximately is, for example, 7.0 Å. The layer thickness difference of SiO₂ between on the surfaces 120a and on the surfaces 110a in 50 ALD cycles approximately is, for example, 9.1 Å. With the first formation method example, it is possible to ensure the degree of selectiveness described above.

As described above, in the first structure example of each NAND string NS in the embodiment, since the insulation part 5 is formed, it is possible to improve captured electron density in overlapping regions of the charge trap film 42 with the conductive layers 11 in the X-axis direction or the Y-axis direction at, for example, data writing, thereby reducing electric interference between adjacent memory cells MC. Moreover, since the insulation part 5 is curved in a convex shape toward the semiconductor layer 3, it is possible to reduce electric field concentration near the end part 12E, for example. Thus, malfunction of memory cells MC can be reduced.

In the first formation method example, the Si precursor contains an amino group. Accordingly, the Si precursor is selectively adsorbed onto an OH group existing on the surfaces 120a among the surfaces 110a and 120a exposed in coexistence. Moreover, an oxidant with small oxidation power is used since the Si precursor contains an alkoxy group. Accordingly, it is possible to reduce oxidation of SiN on the surfaces 110a, thereby preventing the NH group on the surfaces 110a from being replaced with an OH group. This can make it easier to selectively grow SiO₂ on the surfaces 120a. In other words, selectiveness can be increased.

In the first formation method example, no additional process for increasing selectiveness is needed. Thus, selectiveness can be increased without process complication.

Since the oxidation power of the oxidant is small, SiO₂ can be grown by the ALD at low temperature. The treatment temperature of the ALD is, for example, 300° C. to 600° C.

As for the amino group, activation energy difference in chemical adsorption reaction between an OH group and an NH group is maximum in a case where the ligand is an isopropyl group. Thus, from the perspective of selectiveness, the amino group is preferably, for example, a dialkylamino group, and the dialkylamino group is preferably, for example, a diisopropylamino group.

The alkoxy group is, for example, a methoxy group or an ethoxy group.

The Si precursor may be monosilane (aminoalkoxysilane) containing an amino group and an alkoxy group or may be disilane (aminoalkoxydisilane) containing an amino group and an alkoxy group.

As a comparative example, an amino silane is used as the Si precursor in some cases. In such a case, an oxidant containing an oxygen radical or ozone with larger oxidation power than O₂ or H₂O is used. However, with large oxidation power, SiN on the surfaces 110a is oxidized and the NH group on the surfaces 110a is replaced with an OH group. As a result, SiO₂ is likely to be wrongly grown on the surfaces 110a.

However, in the first formation method example, the Si precursor contains an alkoxy group. Accordingly, the ALD can be performed by using an oxidant with small oxidation power. As a result, it is possible to reduce oxidation of SiN on the surfaces 110a, thereby preventing the NH group on the surfaces 110a from being replaced with an OH group. This can make it easier to selectively grow SiO₂ on the surfaces 120a. In other words, selectiveness can be increased.

### Second Formation Method Example for First Structure Example of Each NAND String NS

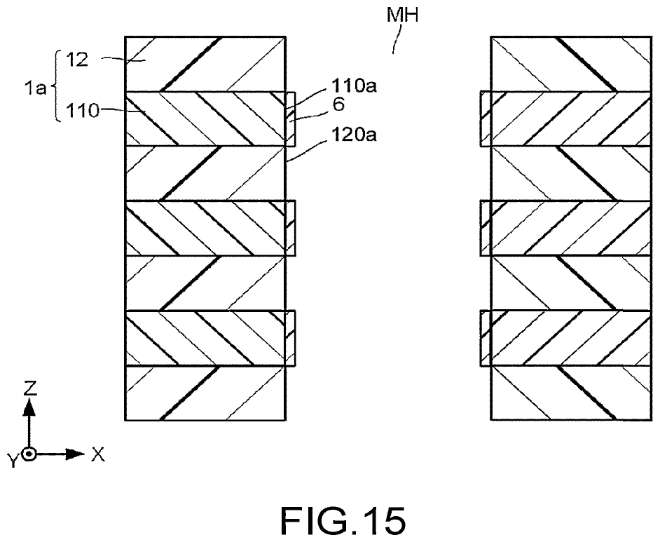

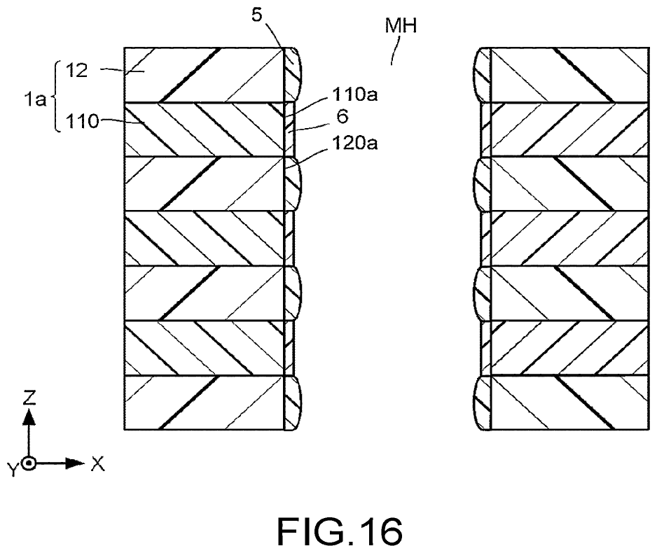

A second formation method example for the first structure example of each NAND string NS in the semiconductor storage device manufacturing method will be described below with reference to FIGS. 15 and 16. FIGS. 15 and 16 are schematic sectional views for description of the second formation method example for the first structure example of each NAND string NS, and illustrate part of an X-Z section.

The second formation method example is different from the first formation method example in that a protective film 6 is formed.

First, as in the first formation method example, the memory hole MH is formed by the processes illustrated in FIGS. 6 and 7, and then the protective film 6 is formed on the surfaces 110a as illustrated in FIG. 15 and the insulation part 5 is selectively formed on the surfaces 120a of the insulating layers 12 as illustrated in FIG. 16. Selectiveness can be increased by covering parts of the surfaces with a protective film such as an insulating film and changing layer thickness and composition at the other parts of the surfaces. In other words, the protective film 6 encumbers adsorption of the Si precursor onto the surfaces 110a. For example, in a case where the insulation part 5 containing silicon oxide is formed, the protective film 6 is formed by reforming the surfaces 110a by using, for example, an inhibitor that can be selectively adsorbed onto the NH group existing on the surfaces 110a of the insulating layers 110 as silicon nitride films. Subsequently, under low temperature at which the protective film 6 is not desorbed from the surfaces 110a, the insulation part 5 is formed by using an oxidant and a Si precursor that can be selectively adsorbed onto the OH group on the surfaces 120a of the insulating layers 12 as silicon oxide films. The Si precursor and the oxidant may be the same as the Si precursor and the oxidant described above in the first formation method example. The protective film 6 can be formed by using, for example, the CVD or the ALD but may be formed by using a method such as application.

More specifically, in one ALD cycle, before the Si precursor is supplied, gas containing CI is supplied as the inhibitor and vacuuming/purging is performed. From the activation energy relation between the OH group and the NH group, CI is selectively adsorbed onto the NH group and the surfaces 110a are selectively terminated with SiCl. Accordingly, the surfaces 110a can be further prevented from being oxidized and formed with the OH group. The gas containing CI contains, for example, chlorosilane or HCl. Chlorosilane contains, for example, SiCl₄, SiHCl₃, or SiH₂Cl₂. Supply of the gas containing CI may be performed in each ALD cycle or in at least one of a plurality of ALD cycles.

Thereafter, the processes illustrated in FIG. 9 and the following drawings are performed. The protective film 6 is formed by outermost surface reforming and thus is extremely thin and does not need to be removed. In a case where a thick protective film 6 is formed, the protective film 6 may be removed by, for example, dry etching or wet etching.

In the second formation method example, since gas containing Cl is used as the inhibitor, the Si precursor can be further prevented from being adsorbed onto the surfaces 110a as SiN. As a result, selectiveness can be increased.

### Second Structure Example of NAND String NS

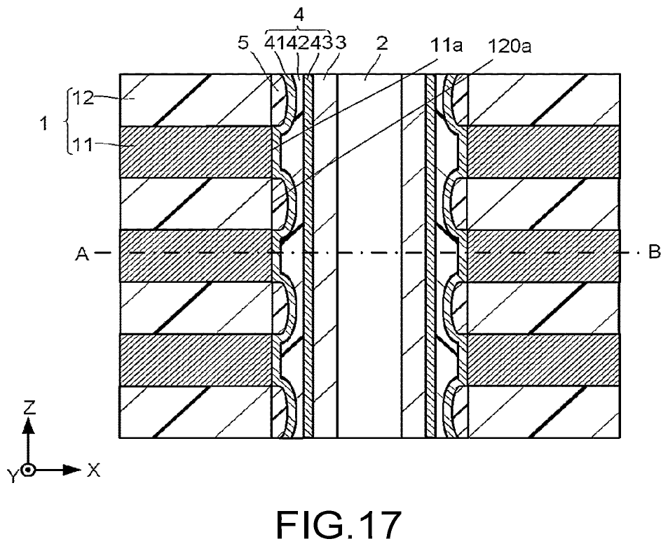

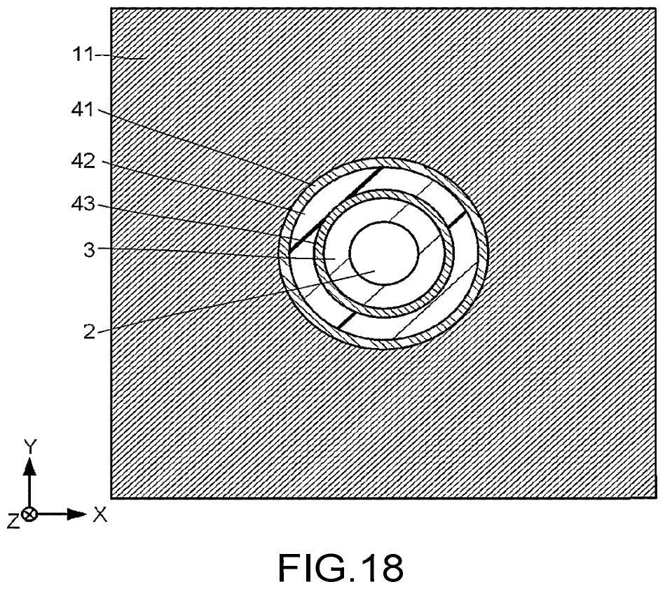

FIG. 17 is a cross-sectional schematic diagram for description of the second structure example of each NAND string NS in the embodiment. FIG. 17 illustrates an X axis, a Y axis orthogonal to the X axis, and a Z axis orthogonal to the X and Y axes and illustrates part of an X-Z section including the X and Z axes. FIG. 18 is a cross-sectional schematic diagram along line segment A-B in FIG. 17 and illustrates part of an X-Y section including the X and Y axes.

As illustrated in FIGS. 17 and 18, each NAND string NS includes a stacked body 1, an insulator 2, a semiconductor layer 3, a memory layer 4, and an insulation part 5.

As illustrated in FIG. 18, the semiconductor layer 3 surrounds the insulator 2 at the section A-B. The semiconductor layer 3 penetrates through the stacked body 1 in the Z-axis direction. The other description of the semiconductor layer 3 can be replaced with description of the semiconductor layer 3 illustrated in FIG. 3 as appropriate.

The memory layer 4 is provided on a side opposite the insulator 2 of the semiconductor layer 3. The memory layer 4 is provided between each conductive layer 11 and the semiconductor layer 3 in the X-axis direction or the Y-axis direction.

The memory layer 4 includes the block insulating film 41, the charge trap film 42, and the tunnel insulating film 43. The block insulating film 41 is provided between the insulation part 5 and the semiconductor layer 3 in the X-axis direction or the Y-axis direction. The charge trap film 42 is provided between the tunnel insulating film 43 and the block insulating film 41 in the X-axis direction or the Y-axis direction. The tunnel insulating film 43 is provided between the charge trap film 42 and the semiconductor layer 3. The other description of the block insulating film 41, the charge trap film 42, and the tunnel insulating film 43 can be replaced with description of the block insulating film 41, the charge trap film 42, and the tunnel insulating film 43 illustrated in FIG. 3 as appropriate.

The insulation part 5 extends from each insulating layer 12 toward the semiconductor layer 3 in the X-axis direction or the Y-axis direction. The insulation part 5 is provided on each surface 120a. The insulation part 5 is provided between each insulating layer 12 and the memory layer 4. The other description of the insulation part 5 can be replaced with description of the insulation part 5 illustrated in FIG. 3 as appropriate.

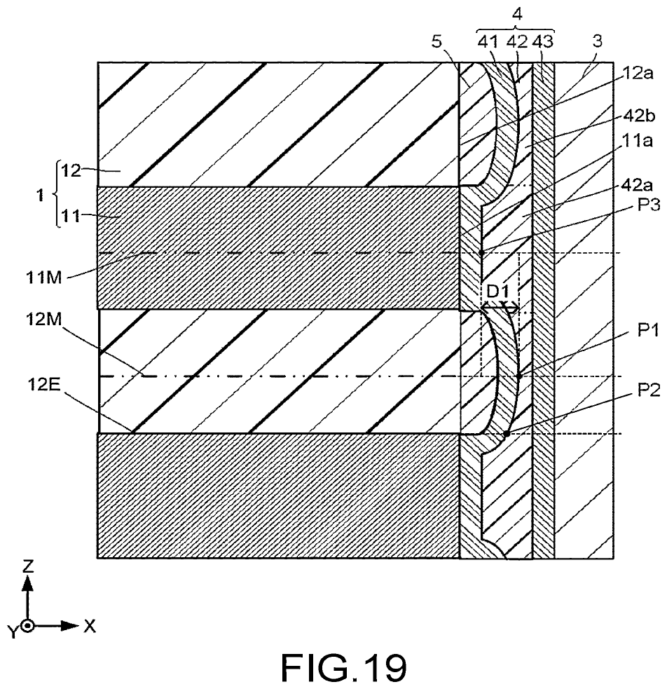

FIG. 19 is an enlarged view illustrating part of FIG. 17. At a section of the NAND string NS in the Z-axis direction, including the conductive layers 11, the insulating layers 12, the semiconductor layer 3, the memory layer 4, and the insulation part 5, each of the interface between the block insulating film 41 and the charge trap film 42, the interface between the charge trap film 42 and the tunnel insulating film 43, and the interface between the tunnel insulating film 43 and the semiconductor layer 3 includes a first part, a second part, and a third part. In the X-axis direction or the Y-axis direction, the first part overlaps a central part 12M of an insulating layer 12 in the Z-axis direction. In the X-axis direction or the Y-axis direction, the second part overlaps an end part 12E of an insulating layer 12 in the Z-axis direction. The third part overlaps a central part 11M of a conductive layer 11 in the Z-axis direction. The central part 11M is a region positioned at a depth separated from the upper surface or lower surface of the conductive layer 11 by half of the thickness (length in the Z-axis direction) of the conductive layer 11. The central part 12M is, for example, a region positioned at a depth separated from the upper surface or lower surface of the insulating layer 12 by half of the thickness (length in the Z-axis direction) of the insulating layer 12. The end part 12E is a region contacting an end part of the conductive layer 11 in the Z-axis direction. The second part is provided on each of the upper and lower sides of the first part. FIG. 19 illustrates an example in which the interface between the block insulating film 41 and the charge trap film 42 includes a part P1 overlapping the central part 12M of the insulating layer 12 in the Z-axis direction, a part P2 overlapping the end part 12E, and a part P3 overlapping the central part 11M.

At each interface, the second part is closer to the insulating layer 12 than the first part in the X-axis direction or the Y-axis direction. Each interface has a round or arch shape protruding toward the memory layer 4. Each interface curves in a convex shape toward the semiconductor layer 3 from the second parts on the upper and lower sides to the first part. For example, the interface between the block insulating film 41 and the charge trap 42 curves in a convex shape toward the semiconductor layer 3 from the parts P2 on the upper and lower sides to the part P1 as illustrated in FIG. 19.

At each interface, an interval D1 between the first part and the third part in the X-axis direction or the Y-axis direction is preferably equal to or larger than 2 nm and equal to or smaller than 7 nm. In a case where the interval D1 is smaller than 2 nm, it is difficult to prevent electric interference between adjacent memory cells MC. In a case where the interval D1 is larger than 7 nm, electric field concentrates at the central part 11M in accordance with voltage applied when data is written to memory cells MC, and as a result, writing efficiency decreases in some cases.

The thickness (length in the X-axis direction or the Y-axis direction) of the insulation part 5 may decrease from the first part toward the second part of each interface. The thickness of the insulation part 5 is preferably equal to or larger than 2 nm and equal to or smaller than 7 nm. This means that the thickness of the entire region from a part where the thickness of the insulation part 5 is minimum to a part where the thickness of the insulation part 5 is maximum may be equal to or larger than 2 nm and equal to or smaller than 7 nm.

The thickness of the charge trap film 42 (length of the charge trap film 42 in the X-axis or Y-axis direction) may increase from the first part toward the second part of each interface. The thickness of the charge trap film 42 in a region overlapping the first part is preferably smaller than the thickness of the insulation part 5. Accordingly, the charge trap film 42 can have a large electron capturing region, and thus, for example, decrease of writing characteristics can be reduced. The thickness of the charge trap film 42 is preferably, for example, equal to or larger than 2 nm and equal to or smaller than 10 nm. In a case where the thickness of the charge trap film 42 is smaller than 2 nm, electric charge capturing performance degrades, and for example, writing characteristics decrease. In a case where the thickness of the charge trap film 42 is larger than 10 nm, electric interference between adjacent memory cells MC increases.

The charge trap film 42 includes a region 42a and a region 42b. The region 42a overlaps the conductive layer 11 in the X-axis direction or the Y-axis direction, and the region 42b overlaps the insulation part 5 in the X-axis direction or the Y-axis direction. FIG. 19 illustrates the boundary between the regions 42a and 42b with a dashed and double-dotted line. The region 42b preferably has a thickness smaller than the thickness of the region 42a in the X-axis direction or the Y-axis direction. Accordingly, electric interference between adjacent memory cells MC can be reduced. However, the present invention is not limited thereto, and the charge trap film 42 may be thin and include a plurality of divided regions 42a without forming the region 42b.

In the second structure example of each NAND string NS in the semiconductor storage device manufacturing method, as well, the insulation part 5 is formed by the process (first formation method example) illustrated in FIG. 8 or the process (second formation method example) illustrated in FIGS. 15 and 16.

As described above, in the second structure example of each NAND string NS, since the insulation part 5 is formed, it is possible to improve captured electron density in overlapping regions of the charge trap film 42 with the conductive layers 11 in the X-axis direction or the Y-axis direction at, for example, data writing, thereby reducing electric interference between adjacent memory cells MC. Moreover, since the insulation part 5 is curved in a convex shape toward the semiconductor layer 3, it is possible to reduce electric field concentration at the interface between the block insulating film 41 and the charge trap film 42, for example. In addition, since the thickness of the charge trap film 42 increases from the first part toward the second part of each interface, it is possible to prevent the degradation of electric charge loss without increasing the aspect ratio of the memory hole MH, for example. Thus, malfunction of the memory cells MC can be reduced.

The constituent components of the second structure example may be combined with the constituent components of the first structure example as appropriate.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device manufacturing method comprising:
forming a structure including a first surface and a second surface, the first surface containing SiO₂ and being exposed, the second surface containing SiN, being exposed, and provided at a position different from a position of the first surface; and
selectively forming an insulation part containing SiO₂ on the first surface,
wherein selectively forming the insulation part on the first surface includes performing treatment using a Si precursor and an oxidant, the Si precursor containing an amino group and an alkoxy group, the oxidant containing O₂ or H₂O.

2. The semiconductor device manufacturing method according to claim 1, wherein the Si precursor is aminoalkoxysilane or aminoalkoxydisilane, or diisopropylaminotriethoxylsilane.

3. The semiconductor device manufacturing method according to claim 1, wherein the amino group is a dialkylamino group.

4. The semiconductor device manufacturing method according to claim 2, wherein the amino group is a dialkylamino group.

5. The semiconductor device manufacturing method according to claim 3, wherein the dialkylamino group is a diisopropylamino group.

6. The semiconductor device manufacturing method according to claim 4, wherein the dialkylamino group is a diisopropylamino group.

7. The semiconductor device manufacturing method according to claim 1, wherein the alkoxy group is a methoxy group or an ethoxy group.

8. The semiconductor device manufacturing method according to claim 2, wherein the alkoxy group is a methoxy group or an ethoxy group.

9. The semiconductor device manufacturing method according to claim 3, wherein the alkoxy group is a methoxy group or an ethoxy group.

10. The semiconductor device manufacturing method according to claim 4, wherein the alkoxy group is a methoxy group or an ethoxy group.

11. The semiconductor device manufacturing method according to claim 5, wherein the alkoxy group is a methoxy group or an ethoxy group.

12. The semiconductor device manufacturing method according to claim 6, wherein the alkoxy group is a methoxy group or an ethoxy group.

13. The semiconductor device manufacturing method according to claim 1, wherein a temperature of the treatment is 300° C. to 600° C.

14. The semiconductor device manufacturing method according to claim 1, wherein
the treatment is atomic layer deposition (ALD) including repeating an ALD cycle a plurality of times, and
the ALD cycle includes
supplying gas containing the Si precursor,
purging the gas containing the Si precursor,
supplying gas containing the oxidant, and
purging the gas containing the oxidant.

15. The semiconductor device manufacturing method according to claim 14, wherein at least one of the plurality of ALD cycles further includes, before supplying the gas containing the Si precursor,
supplying gas containing CI, and
purging the gas containing Cl.

16. The semiconductor device manufacturing method according to claim 15, wherein the gas containing CI contains chlorosilane or HCl.

17. The semiconductor device manufacturing method according to claim 1, wherein
forming the structure includes
forming a stacked body in which first layers containing SiO₂ and second layers containing SiN are alternately stacked in a first direction, and
forming a hole penetrating through the stacked body in the first direction, and
the first surface and the second surface are exposed on an inner surface of the hole.
